(19) United States
(12) Patent Application Publication
(10) Pub. No.: US 2026/0090365 A1
(43) Pub. Date: Mar. 26, 2026

(54) NITRIDE-RICH CARBIDE LAYERS ON METAL LINES FOR IMPROVED ELECTROMIGRATION

(71) Applicant: Intel Corporation, Santa Clara, CA (US)

(72) Inventors: Dominic A. Esan, Hillsboro, OR (US); Qing Su, Portland, OR (US); Yung-Jih Yang, Hillsboro, OR (US); Ahmad Al-Kukhun, Beaverton, OR (US); Sunny Chugh, Hillsboro, OR (US); Danielle C. Casillas, Portland, OR (US)

(73) Assignee: Intel Corporation, Santa Clara, CA (US)

(21) Appl. No.: 18/898,322

(22) Filed: Sep. 26, 2024

(51) Int. Cl. H01L 23/532; H01L 21/768; H01L 23/528

(52) U.S. Cl. CPC H10W 20/47; H10W 20/069; H10W 20/075; H10W 20/425; H10W 20/435

(57) ABSTRACT

A conformal nitride-rich carbide layer located on a dielectric-on-dielectric layer (a dielectric layer located on an interlayer dielectric) and metal line cap layers in an interconnect stack of an integrated circuit structure provides for improved electromigration. The carbide layer can enable integrated circuit structures to have a reduced topography prior to etch stop stack formation. In addition to enabling improved electromigration of the metal lines the carbide layers can reduce the current leakage between metal lines and nearby vias.

### BACKGROUND

Electromigration, which is the movement of material in an electrical conductor due to the transfer of momentum between conducting electrons and metal ions in the conductor, is a reliability concern in metal lines in integrated circuit structures.

### BRIEF DESCRIPTION OF THE DRAWINGS

FIG. 1 is a cross-sectional view of a portion of an interconnect stack.

FIG. 2 is a cross-sectional view of a portion of an example interconnect stack with a carbide layer positioned between metal line cap layers and an etch stop stack.

FIGS. 3A-3E are cross-sectional views of a portion of an integrated circuit structure comprising a carbide layer located on a dielectric-on-dielectric layer and a metal line cap layer during variation stages of fabrication.

FIG. 4 is an example method of forming an integrated circuit structure comprising a carbide layer located on a dielectric-on-dielectric layer and a metal line cap layer.

FIG. 5 is a top view of a wafer and dies that may be included in a microelectronic assembly, in accordance with any of the embodiments disclosed herein.

FIG. 6 is a cross-sectional side view of an integrated circuit device that may be included in a microelectronic assembly, in accordance with any of the embodiments disclosed herein.

FIG. 7 is a cross-sectional side view of an integrated circuit device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

As semiconductor manufacturing technology enters the angstrom era, the pitch of lower metal layers in the interconnect stack gets tighter (e.g., less than 25 nanometers) and innovations are needed to enable high-volume manufacturability of these interconnect stacks while meeting stringent reliability goals. These interconnect stack innovations include fully self-aligned via schemes that use selective dielectric-on-dielectric (DoD) deposition. The presence of a “DoD” layer on an interlayer dielectric (ILD) can increase the distance between a first metal line and a nearby via connecting to a nearby second metal line, which can reduce via shorting and help meet dielectric reliability goals.

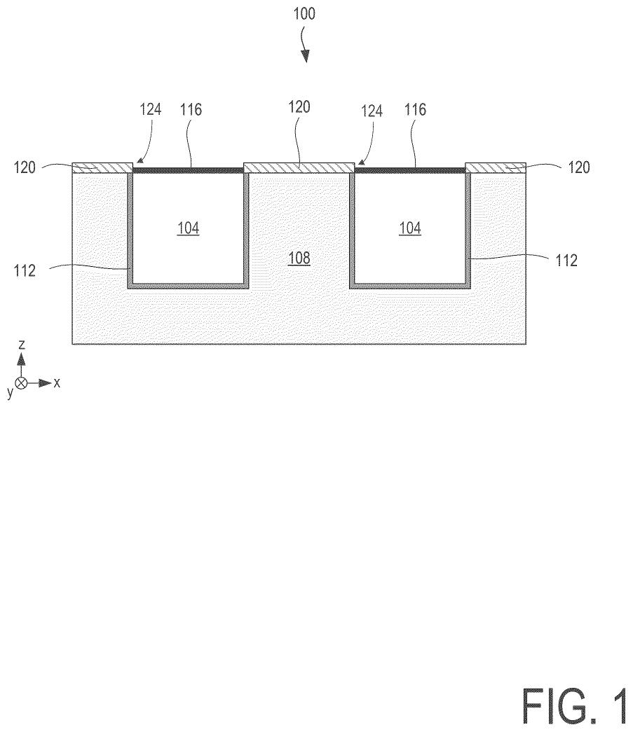

The use of a dielectric-on-dielectric layer in an interconnect stack (or metallization stack) is illustrated in FIG. 1, which is a cross-sectional view of a portion of an interconnect stack. The interconnect stack portion 100 comprises metal lines 104 in interlayer dielectric (ILD) 108. Liner layers 112 are positioned between the metal lines 104 and the interlayer dielectric 108. Portions of a cap layer 116 are located on top surfaces of the metal lines 104 and portions of a dielectric layer 120—a “DoD” layer—are located on a top surface of the interlayer dielectric 108. The cap layer portions 116 are positioned adjacent to and between portions of the dielectric layer 120.

One challenge with integrating a fully self-aligned via scheme with dielectric-on-dielectric layer, such as layer 120, into semiconductor manufacturing flows is the topography introduced by the presence of the dielectric-on-dielectric layer. This topography is represented by height differences 124 in the top surfaces of the dielectric layer 120 and the cap layer 116. Forming an etch stop stack on a surface of an integrated circuit structure possessing such a topography can lead to electromigration reliability concerns in the metal lines, particularly at the corners of the metal lines 104 (where the metal lines 104 meet a liner layer, such as liner layer 112.

In some existing approaches to reduce electromigration in metal lines comprising copper, an oxygen-free initial deposition process is performed prior to formation of an etch stop stack over the metal lines to reduce copper nodule formation and waviness of the metal lines, thereby improving the resistance of the metal lines to electromigration. This initial deposition process forms a layer (an initial deposition layer) on a cap layer located on the metal lines and the interlayer dielectric within which the metal lines are located. This initial deposition is performed at a relatively high deposition rate to prevent copper migration and oxidation at the relatively high deposition temperature at which the initial deposition process is performed. These initial deposition processes can improve the electromigration time-to-failure of copper metal lines relative to processing flows that do not possess these initial deposition layers. However, these initial deposition processes do not work with tighter metal line pitches and produce non-planar surfaces an integrated circuit structures upon which etch stop stacks are to be formed.

Disclosed herein are nitride-rich carbide layers on metal lines for improved electromigration. The layers can be nitride-rich silicon carbide (SiC) layers. These layers can be deposited at a deposition rate lower than in the initial deposition processes mentioned above. These carbide layers can have a thickness of about two nanometers. These layers can conformally coat dielectric-on-dielectric layers located on an interlayer dielectric and cap layers located on metal lines.

The carbide layers disclosed herein have at least the following advantages. They can reduce the topography of the top surface of an integrated circuit structure prior to etch stop stack formation relative to integrated circuit structures not having the disclosed carbide layers. Additionally, they can be denser than the initial deposition layers described above and can enable lower leakage currents between metal lines and nearby vias. They can also enable metal lines having a tight pitch (less than 30 nanometers) that meet electromigration reliability goals without having to develop or integrate alternative processing schemes, such as a tri-layer etch stop stack with a conformal atomic layer deposition (ALD) aluminum oxide layer as the dielectric-on-dielectric layer and innovative etches to eliminate via shorting. Such alternative schemes can be expensive.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a first layer that is substantially parallel to a second layer includes first and second layers that are within 10 degrees of being parallel with each other. Values modified by the word “about” include values within +/−10% of the listed values.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the phrase “electrically coupled” refers to the presence of one or more electrically conductive paths between components that are recited as being electrically coupled.

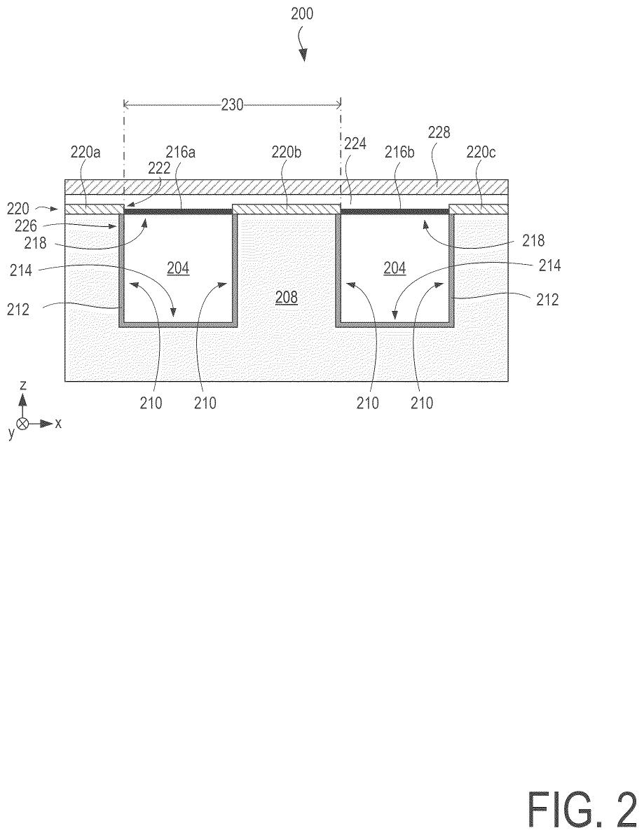

As used herein, the term “adjacent” refers to layers or components that are positioned laterally (in the x- or y-dimensions) next to each other. For example, with reference to FIG. 2, cap layer portion 216a is positioned adjacent to dielectric layer portions 220a and 220b.

Certain terminology may also be used herein for the purpose of reference only, and thus are not intended to be limiting. For example, terms such as “upper,” “lower,” “above,” “below,” “bottom,”and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

FIG. 2 is a cross-sectional view of a portion of an example interconnect stack with a carbide layer positioned between metal line cap layers and an etch stop stack. The interconnect stack portion 200 comprises metal lines 204 belonging to one interconnect layer (or metallization layer) of the interconnect stack. The metal lines 204 are located within an interlayer dielectric (ILD) 208. The metal lines 204 are located within the interlayer dielectric 208 in that the interlayer dielectric 208 surrounds sidewalls 210 and bottom surfaces 214 of the metal lines 204. In other embodiments, the interlayer dielectric 208 may only surround the bottom surfaces 214 along a portion of the length of the metal lines 204 if the metal lines 204 are connected to one or more vias (or contacts) that electrically couple the metal lines 204 to a lower-level metal line in the interconnect stack or a device terminal, such as a transistor gate, source, or drain terminal. In some embodiments, where the bottom surfaces of the metal lines are substantially coplanar with the bottom surface of an interlayer dielectric, the metal lines are located within an interlayer dielectric in that the interlayer dielectric surrounds at least the sidewalls of the metal lines.

Liner layers 212 are positioned between the metal lines 204 and the interlayer dielectric 208. A cap layer 216 (or metal layer) comprising portions 216a and 216b is located on top surfaces 218 of the metal lines 204 and a dielectric layer 220 is located on top surfaces of the interlayer dielectric 208. The cap layer 216 comprises portions 216a and 216b that are positioned adjacent to and between portions 220a, 220b, and 220c of the dielectric layer 220. A carbide layer 224 is located on the cap layer 216 and the dielectric layer 220, and an etch stop stack 228 is located on the carbide layer 224. The carbide layer 224 is positioned between the etch stop stack 228, and the cap layer 216 and the dielectric layer 220.

The interlayer dielectric 208 can comprise any suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen), or other suitable dielectric material.

The metal lines 204 can comprise copper or another suitable metal. In some embodiments, the metal lines comprise copper and manganese, with the metal lines having an atomic concentration of less than 10% manganese. The liner layers 212 can act as diffusion barriers, adhesion layers, and/or seed layers for the metal lines 204. The liner layers 212 can comprise ruthenium-cobalt, ruthenium-tantalum, titanium, cobalt, titanium nitride (TiN), tantalum-doped titanium nitride (Ta-doped TiN), tantalum nitride (TaN), titanium-doped tantalum nitride (Ti-doped TaN), or other suitable material. The metal lines have a pitch 230. In some embodiments, the pitch 230 is about 30 nanometers or less.

The cap layer 216 can improve the electromigration resistance of the metal lines 204. The cap layer 216 can comprise cobalt, molybdenum, or another suitable metal. The cap layer 216 can have a thickness in the range of about 1.5 to about 2.0 nanometers, such as about 1.5 nm, about 1.8 nm, or about 2.0 nm. Individual portions of the cap layer 216 are positioned adjacent to and between portions of the dielectric layer 220. For example, cap layer portion 216a is positioned between and adjacent to portions 220a and 220b of dielectric layer 220.

The dielectric layer 220 is a “dielectric-on-dielectric” layer as discussed above and can improve the resistance of an integrated circuit structure to via shorting (the shorting of a metal line to a nearby via) by increasing the distance between metal lines and nearby vias. The dielectric layer 220 comprises portions 220a, 220b, and 220c positioned adjacent to portions 216a and 216b of the cap layer 216. The dielectric layer 220 is located on the interlayer dielectric 208 in that the dielectric layer 220 is positioned predominantly over a top surface of the interlayer dielectric 208. In some embodiments, due to process bias or variations, or intentional design, a portion of the dielectric layer 220 may extend past a top surface edge of the interlayer dielectric 208. For example, edge 222 of dielectric layer portion 220a extends past an edge 226 of the interlayer dielectric 208 and over a sidewall of a liner layer 212. An edge of a portion of a dielectric layer that extends past a top surface edge of an interlayer dielectric is still considered to be located on the interlayer dielectric. That is, for example, edge 222 is considered to be located on interlayer dielectric 208.

The dielectric layer 220 can comprise aluminum oxide (Al₂O₃), silica-doped aluminum oxide (Al₂O₃ doped with SiO₂), or other suitable material. The dielectric layer 220 can have a thickness of about two nanometers or greater, such as about 2.0 nm, about 2.5 nm, or about 3.0 nm. As illustrated in FIG. 2, as well as discussed above in regard to FIG. 1, the dielectric layer 220 can have a thickness greater than the cap layer 216, resulting in a topography on the top surface of an integrated circuit structure after formation of the dielectric layer 220 and the cap layer 216.

The carbide layer 224 comprises nitride-rich silicon carbide (SiC). In some embodiments, the carbide layer 224 has an atomic composition of at least 25 percent nitrogen. In other embodiments, the carbide layer 224 has an atomic composition in a range of 25-30 percent nitrogen. In some embodiments, the carbide layer 224 further comprises hydrogen. In such embodiments, the carbide layer can have an atomic composition of about 25 percent hydrogen. In some embodiments, carbide layer 224 can have a thickness in the range of about 1.0 nanometer to about 2.0 nanometers, such as about 1.0 nm, about 1.5 nm, or about 2.0 nm.

The carbide layer 224 can be formed via deposition at a deposition rate that is slower than the deposition rate used in forming initial deposition layers described above. The carbide layers described herein can have a greater atomic density, hermiticity, and greater conformity relative to the existing initial deposition layer solutions, even at carbide layer thicknesses of about two nanometers. That is, regarding the enhanced relative conformity, the carbide layers 224 can do a better job in more uniformly covering a top surface of an integrated circuit structure that has a dielectric-on-dielectric layer (e.g., 220) and a metal layer (e.g., 216) on its top surface than the initial deposition layers described above. This enhanced conformity and reduced topography can result in enhanced coverage of the carbide layer at the corners of the metal lines as well where the metal lines meet the liner layers. Forming an integrated circuit structure having a reduced top surface topography prior to etch stop stack formation can result in metal lines that meet electromigration reliability requirements for a semiconductor manufacturing process. The carbide layers 224 can further provide for reduced via shorting (as measured by the reduction in leakage current) between a metal line and a nearby via relative to the existing initial deposition layer schemes described above.

The etch stop stack 228 can comprise a plurality of layers that act as an etch stop for the etching of an interlayer dielectric belonging to the next-higher layer in the interconnect stack. In some embodiments, the etch stop stack 228 can comprise a first layer comprising aluminum oxide (Al₂O₃) and a second layer comprising silicon oxynitride carbide (SiOCN, a material comprising silicon, oxygen, carbon, and nitrogen) or silicon oxycarbide (SiOC, a material comprising silicon, oxygen, and carbon), or combinations of other layers comprising suitable materials.

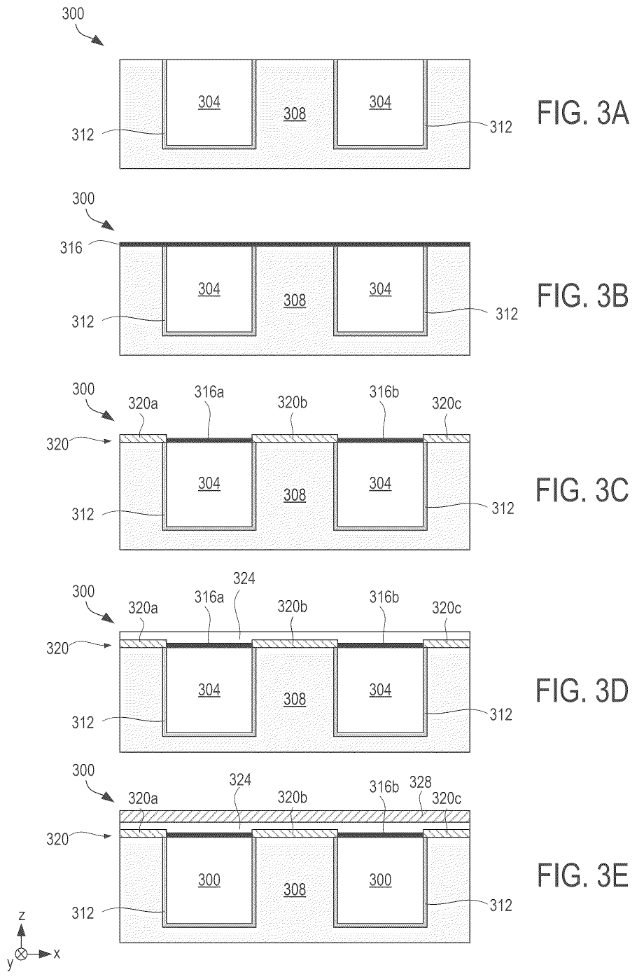

FIGS. 3A-3E are cross-sectional views of a portion of an integrated circuit structure comprising a carbide layer located on a dielectric-on-dielectric layer and a metal line cap layer during various stages of fabrication. The characteristics of the lines, layers, and other elements of FIG. 2 apply to the like-numbered lines, layers, and other elements of FIGS. 3A-3E, as well as FIG. 1 (e.g., the carbide layer 324 can have the same characteristics of carbide layer 224).

FIG. 3A illustrates a portion of an integrated circuit structure portion 300 comprising metal lines 304 located within an interlayer dielectric (ILD) 308. Liner layers 312 are positioned between the metal lines 304 and the interlayer dielectric 308.

FIG. 3B illustrates the integrated circuit structure portion 300 after a cap layer 316 is formed on top surfaces of the metal lines 304 and the interlayer dielectric 308. FIG. 3C illustrates the integrated circuit structure portion 300 after removal of portions of the cap layer 316 that are located on the interlayer dielectric 308 and selective formation of a dielectric layer 320 (a dielectric-on-dielectric layer) located on the interlayer dielectric 308. The dielectric layer 320 comprises portions 320a, 320b, and 320c. Portions 316a and 316b of the cap layer 316 are positioned between and adjacent to portions of the dielectric layer 320.

FIG. 3D illustrates the integrated circuit structure portion 300 after formation of a carbide layer 324 on the portions 316a and 316b of the cap layer 316 and portions 320a, 320b, and 320c of the dielectric layer 320. In some embodiments, the carbide layer 324 is formed via deposition and is deposited at a relatively low deposition rate. The carbide layer can be formed by plasma-enhanced chemical vapor deposition (PECVD), plasma-enhance atomic layer deposition (PEALD), or thermal atomic layer deposition (thermal ALD), or another suitable deposition process. FIG. 3E illustrates the integrated circuit structure portion 300 after formation of an etch stop stack 328 on the carbide layer 324.

It is to be understood that FIGS. 1, 2, and 3A-3E illustrate idealized versions of integrated circuit structure cross-sections. In actual cross-sections, the lines, layers, and other elements illustrated in the figures can have shapes that vary from those illustrated. For example, surfaces illustrated as planar possess undulations, bumps, or dishing features; metal line sidewalls can have a taper to them; ninety-degree corners can be rounded; and lines, layers, and features can overlap more or less than illustrated.

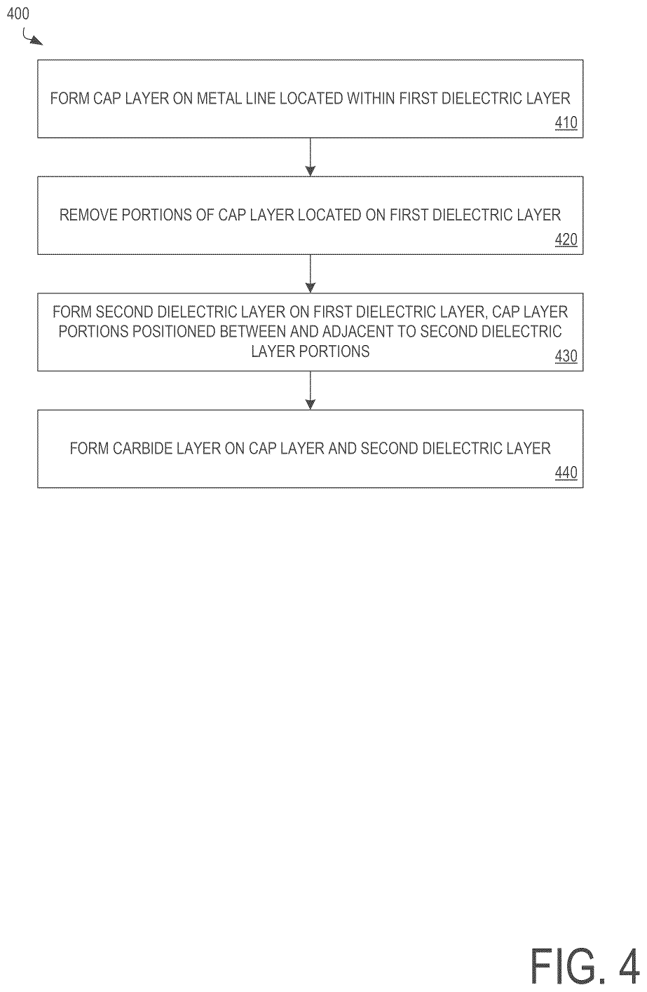

FIG. 4 is an example method of forming an integrated circuit structure comprising a carbide layer located on a dielectric-on-dielectric layer and a metal line cap layer. The method 400 can be performed by, for example, an integrated circuit component manufacturer. At 410, a cap layer is formed on a metal line located within a first dielectric layer, the metal line comprising a first metal, the first dielectric layer comprising a first dielectric material, the cap layer comprising a second metal. At 420, portions of the cap layer that are located on the first dielectric layer are removed. At 430, a second dielectric layer comprising a plurality of second dielectric layer portions that are located on the first dielectric layer is formed, the cap layer positioned between and adjacent to a first portion of the plurality of second dielectric layer portions and a second portion of the plurality of second dielectric layer portions, the second dielectric layer comprising a second dielectric material. At 440, a carbide layer on the cap layer and the second dielectric layer is formed, the carbide layer comprising silicon, carbon, and nitrogen.

In other embodiments, the method 400 can comprise more or fewer elements, a single element of method 400 can be split into two or more elements, and two or more elements of method 400, can be combined into a single element. For example, the method 400 can further comprise forming a plurality of etch stop layers on the carbide layer, wherein one of the plurality of etch stop layers comprises silicon, oxygen, carbon, and nitrogen; or silicon, oxygen, and carbon.

The integrated circuit structures comprising a carbide layer between an etch stop stack and a metal line cap layer can be used in any processor unit or integrated circuit component described or referenced herein. An integrated circuit component comprising such integrated circuit structures can be attached to a printed circuit board. In some embodiments, one or more additional integrated circuit components (such as a memory) or other components (such as a battery or antenna) can be attached to the printed circuit board. In some embodiments, the printed circuit board and the integrated circuit component can be located in a computing device that comprises a housing that encloses the printed circuit board and the integrated circuit component is an integrated circuit structure comprising a carbide layer between an etch stop stack and a metal line cap layer can comprise other types of devices, such as electronic transistors (transistors such as CMOS transistors that operate through control of the flow of electric current and that do not rely upon the switching of the magnetization of a layer or component for operation) or spintronic devices (devices that utilize a physical variable of magnetization (or electron spin) or polarization as a computational variable).

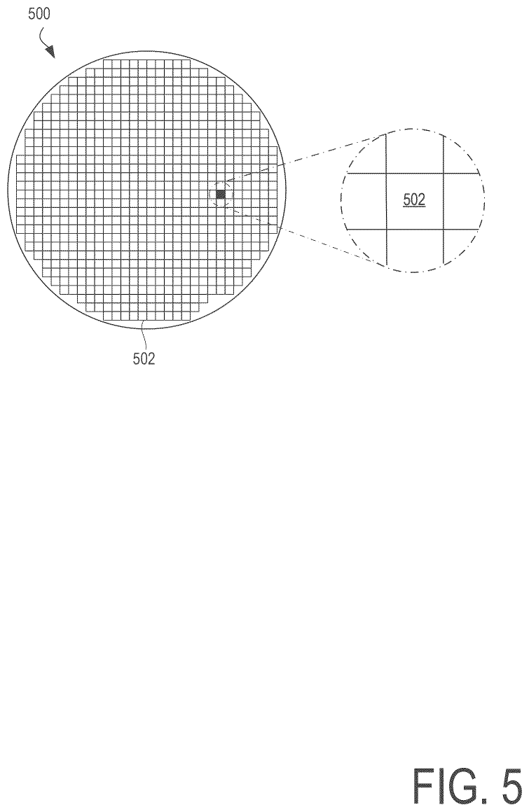

FIG. 5 is a top view of a wafer 500 and integrated circuit dies 502 that may comprise integrated circuit structures comprising carbide layers located on metal lines and dielectric-on-dielectric layers. The wafer 500 may be composed of semiconductor material and may include one or more dies 502 having integrated circuit structures formed on a surface of the wafer 500.

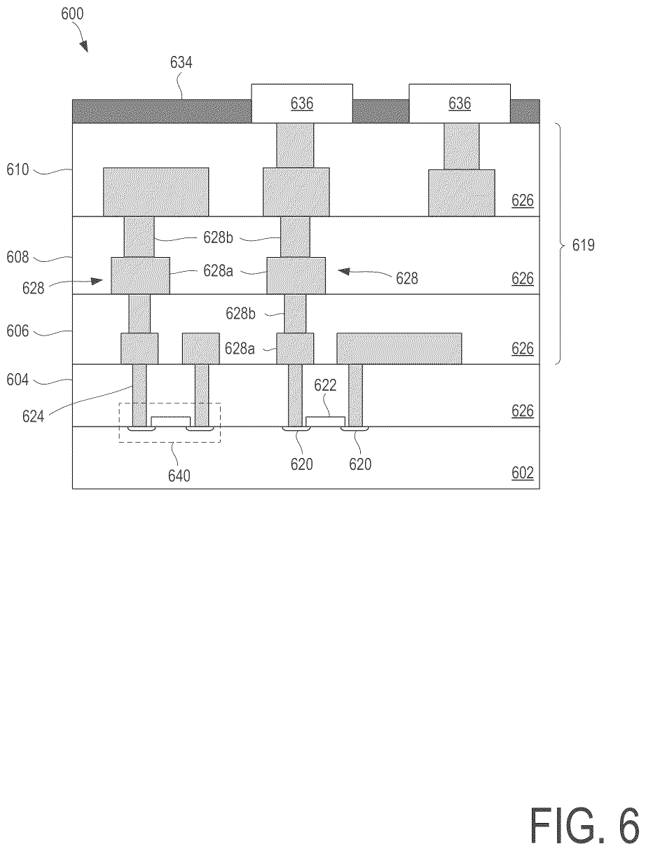

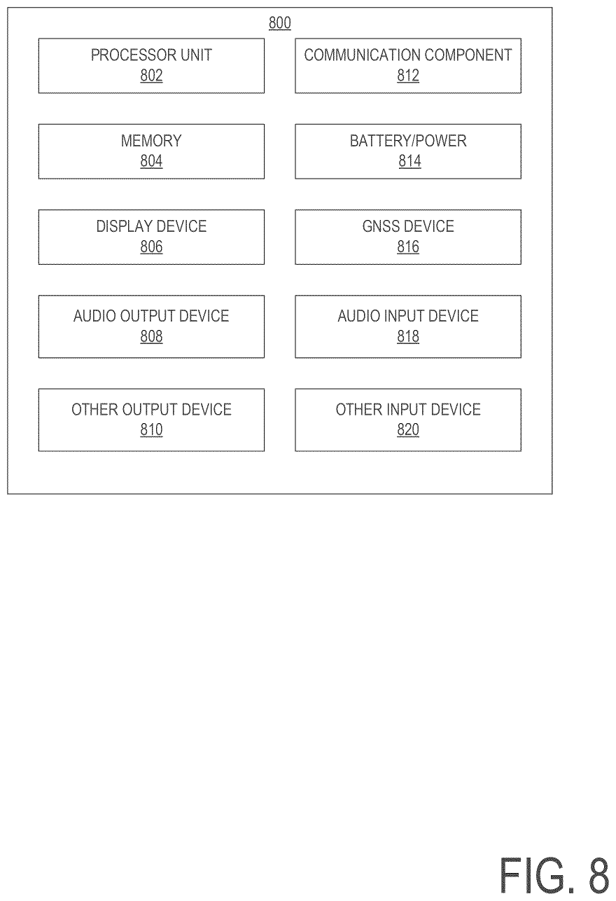

The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array.

FIG. 6 is a cross-sectional side view of an integrated circuit device 600 that may comprise integrated circuit structures comprising carbide layers located on metal lines and dielectric-on-dielectric layers. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack” or “interconnect stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include metal lines 628a and/or vias 628b, as shown. The metal lines 628a of the first interconnect layer 606 may be coupled with contacts (e.g., the S/D contacts 624) of the device layer 604. The vias 628b of the first interconnect layer 606 may be coupled with the metal lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the metal lines 628 of the second interconnect layer 608 with the metal lines 628a of a third interconnect layer 610. Although the metal lines 628a and the vias 628b are structurally delineated with a metal line within individual interconnect layers for the sake of clarity, the metal lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with metal lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

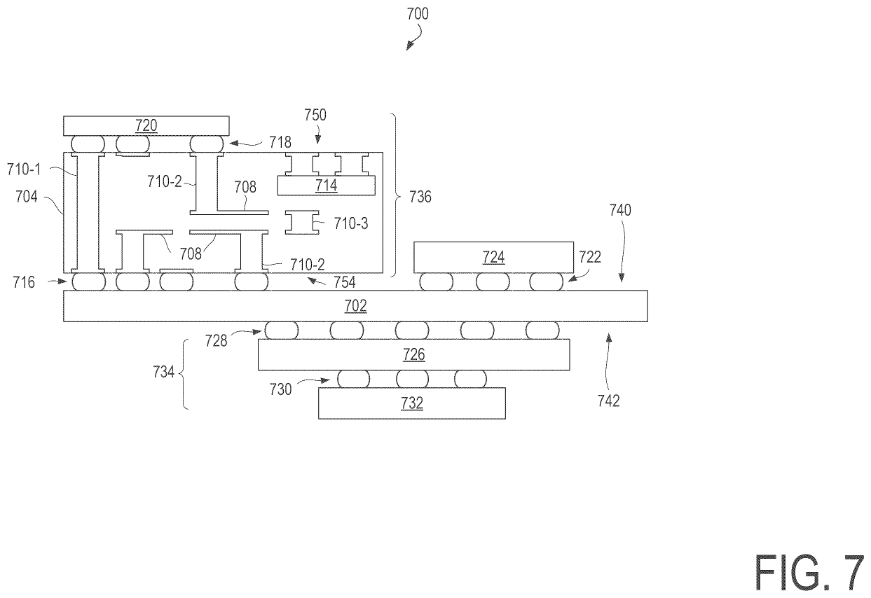

FIG. 7 is a cross-sectional side view of an integrated circuit device assembly 700 that may include integrated circuit structures comprising carbide layers located on metal lines and dielectric-on-dielectric layers. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may take the form of any suitable ones of the embodiments of the microelectronic assemblies disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the microelectronic assemblies disclosed herein. For example, any suitable ones of the components of the electrical device 800 may include one or more of the integrated circuit device assemblies 700, integrated circuit components 720, integrated circuit devices 600, or integrated circuit dies 502 disclosed herein, and may be arranged in any of the microelectronic assemblies disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 818 or an audio output device 808, but may include audio input or output device interface circuitry (e.g., connectors and supporting circuitry) to which an audio input device 818 or audio output device 808 may be coupled.

The electrical device 800 may include one or more processor units 802 (e.g., one or more processor units). As used herein, the terms “processor unit”, “processing unit”, or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols. The electrical device 800 may include an antenna to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 818 (or corresponding interface circuitry, as discussed above). The audio input device 818 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 816 (or corresponding interface circuitry, as discussed above), such as a Global Positioning System (GPS) device. The GNSS device 816 may be in communication with a satellite-based system and may determine a geolocation of the electrical device 800 based on information received from one or more GNSS satellites, as known in the art.

The electrical device 800 may include an other output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include an other input device 820 (or corresponding interface circuitry, as discussed above). Examples of the other input device 820 may include an accelerometer, a gyroscope, an image capture device (e.g., monoscopic or stereoscopic camera), a trackpad, a touchpad, a keyboard, a cursor control device such as a mouse, a stylus, a touchscreen, proximity sensor, microphone, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: a first layer comprising a first dielectric material; a metal line comprising a first metal, the metal line located within the first layer; a second layer comprising a second metal, a portion of the second layer located on the metal line; a third layer comprising a second dielectric material, the third layer positioned on the first layer, the third layer comprising a first portion and a second portion, the portion of the second layer positioned between and adjacent to the first portion of the third layer and the second portion of the third layer; and a fourth layer located on the second layer and the third layer, the fourth layer comprising silicon, carbon, and nitrogen.

Example 2 comprises the apparatus of example 1, wherein the fourth layer comprises an atomic composition of at least 25 percent nitrogen.

Example 3 comprises the apparatus of example 1, wherein the fourth layer comprises an atomic composition in a range of 25 to about 30 percent nitrogen.

Example 4 comprises the apparatus of any one of examples 1-3, wherein the fourth layer has a thickness of about two nanometers.

Example 5 comprises the apparatus of any one of examples 1-4, wherein the fourth layer has a thickness in a range of about 1.0 nanometers to about 2.0 nanometers.

Example 6 comprises the apparatus of any one of examples 1-5, wherein the first metal comprises copper.

Example 7 comprises the apparatus of any one of examples 1-5, wherein the first metal further comprises manganese.

Example 8 comprises the apparatus of any one of examples 1-7, wherein the first layer comprises: silicon and oxygen; silicon, oxygen, and carbon; silicon, oxygen, and fluorine; or silicon, oxygen, and hydrogen.

Example 9 comprises the apparatus of any one of examples 1-8, further comprising a fifth layer positioned between the metal line and the first layer, the fifth layer comprising: ruthenium and cobalt; titanium and nitrogen; titanium, nitrogen, and tantalum; tantalum and nitrogen; tantalum, nitrogen, and titanium; ruthenium and tantalum, titanium; or cobalt.

Example 10 comprises the apparatus of any one of examples 1-9, wherein the second metal comprises cobalt.

Example 11 comprises the apparatus of example 10, wherein the metal line further comprises molybdenum.

Example 12 comprises the apparatus of any one of examples 1-11, wherein the second layer has a thickness in a range of about 1.5 to about 2.0 nanometers.

Example 13 comprises the apparatus of any one of examples 1-11, wherein the second layer has a thickness of about two nanometers.

Example 14 comprises the apparatus of any one of examples 1-13, wherein the third layer comprises aluminum and oxygen.

Example 15 comprises the apparatus of example 14, wherein the third layer further comprises silicon.

Example 16 comprises the apparatus of any one of examples 1-15, wherein a thickness of the third layer is at least two nanometers.

Example 17 comprises the apparatus of any one of examples 1-8 further comprising a plurality of fifth layers located on the fourth layer, wherein one of the plurality of fifth layers comprises silicon, oxygen, carbon, and nitrogen; or silicon, oxygen, and carbon.

Example 18 comprises the apparatus of example 17, wherein the one of the fifth layers is a first one of the plurality of fifth layers, a second one of the plurality of fifth layers comprises aluminum and oxygen.

Example 19 comprises the apparatus of any one of examples 1-18, wherein the metal line is a first metal line, the apparatus further comprising a second metal line within the first layer, the first metal line and the second metal line having a pitch of about 30 nanometers or less.

Example 20 is an apparatus, comprising: a first layer comprising a first dielectric material; a metal line comprising a first metal, the metal line located within the first layer; a second layer comprising a second metal, a portion of the second layer located on the metal line; a third layer comprising a second dielectric material, the third layer located on the first layer, the third layer comprising a first portion and a second portion, the portion of the second layer positioned between and adjacent to the first portion of the third layer and the second portion of the third layer; a fourth layer located on the second layer and the third layer, the fourth layer comprising silicon, carbon, and nitrogen; and a transistor, the metal line electrically coupled to a terminal of the transistor.

Example 21 comprises the apparatus of example 20, wherein the fourth layer comprises an atomic composition of at least 25 percent nitrogen.

Example 22 comprises the apparatus of example 20, wherein the fourth layer comprises an atomic composition in a range of 25 to about 30 percent nitrogen.

Example 23 comprises the apparatus of any one of examples 20-22, wherein the fourth layer has a thickness of about two nanometers.

Example 24 comprises the apparatus of any one of examples 20-23, wherein the fourth layer has a thickness in a range of about 1.0 nanometers to about 2.0 nanometers.

Example 25 comprises the apparatus of any one of examples 20-23, wherein the first metal comprises copper.

Example 26 comprises the apparatus of any one of examples 20-25, wherein the first layer comprises: silicon and oxygen; silicon, oxygen, and carbon; silicon, oxygen, and fluorine; or silicon, oxygen, and hydrogen.

Example 27 comprises the apparatus of any one of examples 20-26, wherein the second metal comprises cobalt.

Example 28 comprises the apparatus of any one of examples 20-27, wherein the third layer comprises aluminum and oxygen.

Example 29 comprises the apparatus of any one of examples 20-28, wherein the metal line is a first metal line, the apparatus further comprising a second metal line within the first layer, the first metal line and the second metal line having a pitch of about 30 nanometers or less.

Example 30 comprises the apparatus of any one of examples 20-29, wherein the apparatus further comprises an integrated circuit component comprising the first layer, the metal line, the second layer, the third layer, and the fourth layer.

Example 31 comprises the apparatus of example 30, further comprising a printed circuit board, the integrated circuit component attached to the printed circuit board.

Example 32 comprises the apparatus of example 31, wherein the integrated circuit component is a first integrated circuit component, the apparatus further comprising a second integrated circuit component attached to the printed circuit board.

Example 33 comprises the apparatus of example 31, the apparatus further comprising an antenna or battery attached to the printed circuit board.

Example 34 is an apparatus, comprising: a first dielectric layer; a metal line comprising a first metal, the metal line located within the first dielectric layer; a metal layer comprising a second metal, a portion of the metal layer located on the metal line; a second dielectric layer located on the first dielectric layer, the second dielectric layer comprising a first portion and a second portion, the portion of metal layer positioned between and adjacent to the first portion of the second dielectric layer and the second portion of the second dielectric layer; and a carbide layer located on the metal layer and the second dielectric layer, the carbide layer comprising silicon, carbon, and nitrogen.

Example 35 comprises the apparatus of example 34, wherein the carbide layer comprises an atomic composition of at least 25 percent nitrogen.

Example 36 comprises the apparatus of example 34, wherein the carbide layer comprises an atomic composition in a range of 25 to about 30 percent nitrogen.

Example 37 comprises the apparatus of any one of examples 34-36, wherein the carbide layer has a thickness of about two nanometers.

Example 38 comprises the apparatus of any one of examples 34-37, wherein the carbide layer has a thickness in a range of about 1.0 nanometers to about 2.0 nanometers.

Example 39 comprises the apparatus of any one of examples 34-38, wherein the first metal comprises copper.

Example 40 comprises the apparatus of any one of examples 34-38, wherein the first metal further comprises manganese.

Example 41 comprises the apparatus of any one of examples 34-40, wherein the first dielectric layer comprises: silicon and oxygen; silicon, oxygen, and carbon; silicon, oxygen, and fluorine; or silicon, oxygen, and hydrogen.

Example 42 comprises the apparatus of any one of examples 34-41, further comprising a liner layer positioned between the metal line and the first dielectric layer, the liner layer comprising: ruthenium and cobalt; titanium and nitrogen; titanium, nitrogen, and tantalum; tantalum and nitrogen; tantalum, nitrogen, and titanium; ruthenium and tantalum, titanium; or cobalt.

Example 43 comprises the apparatus of any one of examples 34-42, wherein the second metal comprises cobalt.

Example 44 comprises the apparatus of example 43, wherein the metal line further comprises molybdenum.

Example 45 comprises the apparatus of any one of examples 34-44, wherein metal layer has a thickness in a range of about 1.5 to about 2.0 nanometers.

Example 46 comprises the apparatus of any one of examples 34-44, wherein metal layer has a thickness of about two nanometers.

Example 47 comprises the apparatus of any one of examples 34-46, wherein the second dielectric layer comprises aluminum and oxygen.

Example 48 comprises the apparatus of example 47, wherein the second dielectric layer further comprises silicon.

Example 49 comprises the apparatus of any one of examples 34-48, wherein a thickness of the second dielectric layer is at least two nanometers.

Example 50 comprises the apparatus of any one of examples 34-49 further comprising a plurality of layers located on the carbide layer, wherein one of the plurality of layers comprises silicon, oxygen, carbon, and nitrogen; or silicon, oxygen, and carbon.

Example 51 comprises the apparatus of example 50, wherein the one of the layers is a first one of the plurality of layers, a second one of the plurality of layers comprises aluminum and oxygen.

Example 52 comprises the apparatus of any one of examples 34-51, wherein the metal line is a first metal line, the apparatus further comprising a second metal line within the first dielectric layer, the first metal line and the second metal line having a pitch of about 30 nanometers or less.

Example 53 is an apparatus, comprising: a first dielectric layer; a metal line comprising a first metal, the metal line located within the first dielectric layer; a metal layer comprising a second metal, a portion of the metal layer located on the metal line; a second dielectric layer located on the first dielectric layer, the second dielectric layer comprising a first portion and a second portion, the portion of the metal layer positioned between and adjacent to the first portion of the second dielectric layer and the second portion of the second dielectric layer; a carbide layer located on the metal layer and the second dielectric layer, the carbide layer comprising silicon, carbon, and nitrogen; and a transistor, the metal line electrically coupled to a terminal of the transistor.

Example 54 comprises the apparatus of example 53, wherein the carbide layer comprises an atomic composition of at least 25 percent nitrogen.

Example 55 comprises the apparatus of example 53, wherein the carbide layer comprises an atomic composition in a range of 25 to about 30 percent nitrogen.

Example 56 comprises the apparatus of any one of examples 53-55, wherein the carbide layer has a thickness of about two nanometers.

Example 57 comprises the apparatus of any one of examples 53-56, wherein the carbide layer has a thickness in a range of about 1.0 nanometers to about 2.0 nanometers.

Example 58 comprises the apparatus of any one of examples 53-56, wherein the first metal comprises copper.

Example 59 comprises the apparatus of any one of examples 53-58, wherein the first dielectric layer comprises: silicon and oxygen; silicon, oxygen, and carbon; silicon, oxygen, and fluorine; or silicon, oxygen, and hydrogen.

Example 60 comprises the apparatus of any one of examples 53-59, wherein the second metal comprises cobalt.

Example 61 comprises the apparatus of any one of examples 53-60, wherein the second dielectric layer comprises aluminum and oxygen.

Example 62 comprises the apparatus of any one of examples 53-61, wherein the metal line is a first metal line, the apparatus further comprising a second metal line within the first dielectric layer, the first metal line and the second metal line having a pitch of about 30 nanometers or less.

Example 63 comprises the apparatus of any one of examples 53-62, wherein the apparatus further comprises an integrated circuit component comprising the first dielectric layer, the metal line, the metal layer, the second dielectric layer, and the carbide layer.

Example 64 comprises the apparatus of example 63, further comprising a printed circuit board, the integrated circuit component attached to the printed circuit board.

Example 65 comprises the apparatus of example 64, wherein the integrated circuit component is a first integrated circuit component, the apparatus further comprising a second integrated circuit component attached to the printed circuit board.

Example 66 comprises the apparatus of example 65, the apparatus further comprising an antenna or battery attached to the printed circuit board.

Example 67 is a method comprising: forming a cap layer on a metal line located within a first dielectric layer, the metal line comprising a first metal, the first dielectric layer comprising a first dielectric material, the cap layer comprising a second metal; removing portions of the cap layer that are located on the first dielectric layer; forming a second dielectric layer comprising a plurality of second dielectric layer portions that are located on the first dielectric layer, the cap layer positioned between and adjacent to a first portion of the plurality of second dielectric layer portions and a second portion of the plurality of second dielectric layer portions, the second dielectric layer comprising a second dielectric material; and forming a carbide layer on the cap layer and the second dielectric layer, the carbide layer comprising silicon, carbon, and nitrogen.

Example 68 comprises the method of example 67, wherein a liner layer is located between the metal line and the first dielectric layer, the liner layer comprising: ruthenium and cobalt; titanium and nitrogen; titanium, nitrogen, and tantalum; tantalum and nitrogen; tantalum, nitrogen, and titanium; ruthenium and tantalum, titanium; or cobalt.

Example 69 comprises the method of example 67, wherein the carbide layer comprises an atomic composition of at least 25 percent nitrogen.

Example 70 comprises the method of example 67, wherein the carbide layer comprises an atomic composition in a range of 25 to about 30 percent nitrogen.

Example 71 comprises the method of any one of examples 67-70, wherein the carbide layer has a thickness of about two nanometers.

Example 72 comprises the method of any one of examples 67-71, wherein the first metal comprises copper.

Example 73 comprises the method of any one of examples 67-72, wherein the first dielectric layer comprises: silicon and oxygen; silicon, oxygen, and carbon; silicon, oxygen, and fluorine; or silicon, oxygen, and hydrogen.

Example 74 comprises the method of any one of examples 67-73, wherein the second metal comprises cobalt.

Example 75 comprises the method of example 74, wherein the metal line further comprises molybdenum.

Example 76 comprises the method of any one of examples 67-75, wherein the second dielectric material comprises aluminum and oxygen.

Example 77 comprises the method of example 76, wherein the second dielectric material further comprises silicon.

Example 78 comprises the method of any one of examples 67-77, wherein a thickness of the second dielectric layer is at least two nanometers.

Example 79 comprises the method of any one of examples 67-78 further comprising forming a plurality of layers located on the carbide layer, wherein one of the plurality of layers comprises silicon, oxygen, carbon, and nitrogen; or silicon, oxygen, and carbon.

Example 80 comprises the method of example 79, wherein the one of the layers is a first one of the plurality of layers, a second one of the plurality of layers comprises aluminum and oxygen.

1. An apparatus, comprising:
a first layer comprising a first dielectric material;
a metal line comprising a first metal, the metal line located within the first layer;
a second layer comprising a second metal, a portion of the second layer located on the metal line;
a third layer comprising a second dielectric material, the third layer positioned on the first layer, the third layer comprising a first portion and a second portion, the portion of the second layer positioned between and adjacent to the first portion of the third layer and the second portion of the third layer; and
a fourth layer located on the second layer and the third layer, the fourth layer comprising silicon, carbon, and nitrogen.

2. The apparatus of claim 1, wherein the fourth layer comprises an atomic composition of at least 25 percent nitrogen.

3. The apparatus of claim 1, wherein the fourth layer comprises an atomic composition in a range of 25 to about 30 percent nitrogen.

4. The apparatus of claim 1, wherein the fourth layer has a thickness in a range of about one nanometers to about two nanometers.

5. The apparatus of claim 1, wherein the first metal comprises copper.

6. The apparatus of claim 1, wherein the second metal comprises cobalt.

7. The apparatus of claim 1, wherein the third layer comprises aluminum and oxygen.

8. The apparatus of claim 1, further comprising a plurality of fifth layers located on the fourth layer, wherein a first one of the plurality of fifth layers comprises silicon, oxygen, carbon, and nitrogen; or silicon, oxygen, and carbon, and a second one of the plurality of fifth layers comprises aluminum and oxygen.

9. The apparatus of claim 1, wherein the metal line is a first metal line, the apparatus further comprising a second metal line within the first layer, the first metal line and the second metal line having a pitch of about 30 nanometers or less.

10. An apparatus, comprising:
a first layer comprising a first dielectric material;
a metal line comprising a first metal, the metal line located within the first layer;
a second layer comprising a second metal, a portion of the second layer located on the metal line;
a third layer comprising a second dielectric material, the third layer located on the first layer, the third layer comprising a first portion and a second portion, the portion of the second layer positioned between and adjacent to the first portion of the third layer and the second portion of the third layer;
a fourth layer located on the second layer and the third layer, the fourth layer comprising silicon, carbon, and nitrogen; and
a transistor, the metal line electrically coupled to a terminal of the transistor.

11. The apparatus of claim 10, wherein the fourth layer comprises an atomic composition of at least 25 percent nitrogen.

12. The apparatus of claim 10, wherein the fourth layer comprises an atomic composition in a range of 25 to about 30 percent nitrogen.

13. The apparatus of claim 10, wherein the first metal comprises copper and the second metal comprises cobalt.

14. The apparatus of claim 10, wherein the apparatus further comprises an integrated circuit component comprising the first layer, the metal line, the second layer, the third layer, and the fourth layer.

15. The apparatus of claim 14, further comprising a printed circuit board, the integrated circuit component attached to the printed circuit board.

16. The apparatus of claim 15, wherein the integrated circuit component is a first integrated circuit component, the apparatus further comprising a second integrated circuit component, an antenna, or a battery attached to the printed circuit board.

17. An apparatus, comprising:
a first dielectric layer;
a metal line comprising a first metal, the metal line located within the first dielectric layer;
a metal layer comprising a second metal, a portion of the metal layer located on the metal line;
a second dielectric layer located on the first dielectric layer, the second dielectric layer comprising a first portion and a second portion, the portion of metal layer positioned between and adjacent to the first portion of the second dielectric layer and the second portion of the second dielectric layer; and
a carbide layer located on the metal layer and the second dielectric layer, the carbide layer comprising silicon, carbon, and nitrogen.

18. The apparatus of claim 17, wherein the carbide layer comprises an atomic composition of at least 25 percent nitrogen.

19. The apparatus of claim 17, wherein the carbide layer comprises an atomic composition in a range of 25 to about 30 percent nitrogen.

20. The apparatus of claim 17, wherein the first metal comprises copper.
